(19) United States
(12) Patent Application Publication
(10) Pub. No.: US 2020/0403643 A1
(43) Pub. Date: Dec. 24, 2020

(54) RAPTOR-Q ENCODING APPARATUS WITH IMPROVED ENCODING DELAY TIME AND METHOD THEREOF

(71) Applicant: Open Stack, Inc., Seongnam-si (KR)

(72) Inventors: Jae Guon NAM, Seongnam-si (KR); Ho Jin CHOI, Seongnam-si (KR)

(21) Appl. No.: 16/801,819

(22) Filed: Feb. 26, 2020

(30) Foreign Application Priority Data
Jun. 19, 2019 (KR) 10-2019-0072956
Nov. 27, 2019 (KR) 10-2019-0154077

(51) Int. Cl. H03M 13/37; H04L 1/00; H03M 13/00

(52) U.S. Cl. CPC H03M 13/3761; H04L 1/0041; H03M 13/6502; H03M 13/373; H04L 1/0057

(57) ABSTRACT

The disclosure provides a technique that can improve a raptorQ encoding delay time by using a source block generated in real time while reducing the number of times that a memory is referred to. In one aspect, an encoding apparatus generates a rearranged operation list by rearranging an operation order of an original operation list according to Gaussian elimination related to raptorQ encoding, where rearranging means rearranging according to a generation order of source symbols. If the operations of the rearranged operation list are performed in order according to source symbols generated in real time, about 90% of operations may be performed in advance just before all source symbols constituting a source block are generated, and also, the number of times that a memory is referred to may be reduced.

### CROSS-REFERENCE TO RELATED APPLICATIONS

This application claims the benefit of Korean Patent Application Nos. 10-2019-0072956, filed on Jun. 19, 2019, and 10-2019-0154077, filed on Nov. 27, 2019, in the Korean Intellectual Property Office, the disclosures of both of which are incorporated herein in their entireties by reference.

### BACKGROUND

### 1. Field

The disclosure relates to a raptorQ encoding apparatus and method, and more particularly, to a raptorQ encoding apparatus and method with an improved encoding delay time to enable transmission of videos generated in real time.

### 2. Description of Related Technology

A user datagram protocol (UDP) transmission method does not secure stable transfer of data packets, unlike a transmission control protocol (TCP) transmission method.

Typically, an automatic repeat request (ARQ) method of detecting, by a receiver, lost packets, requesting a transmitter to retransmit the lost packets, and again receiving the lost packets has been used. However, there are difficulties in applying the ARQ method to real-time broadcasting or real-time video transmission.

Recently, an application layer forward error correction (AL-FEC) encoding scheme by which a transmitter generates and transmits data including repair data capable of repairing loss of original data caused during transmission and a receiver recovers, when a part of the received data is lost, the original data from the received data including the repair data is used.

Among the AL-FEC encoding scheme there is a scheme having a systematic code characteristic.

An AL-FEC encoding scheme having no systematic code characteristic is, for example, an LDPL AL-FEC scheme of RFC 5170 “Low Density Parity Check (LDPC) Staircase and Triangle Forward Error Correction (FEC) Schemes”. According to the LDPC AL-FEC scheme, assuming that repair data of about 10% of every 100 pieces of original data is needed with reference to an average loss rate of a network, a transmitter generates a total of 110 pieces of completely new data B1, B2, . . . , B110 based on original data of A1, A2, . . . , A100 and transmits the data B1, B2, . . . , B110 to a receiver. When the receiver receives pieces of data that are 100 pieces or more than 100 pieces among the 110 pieces of data, the receiver decodes all of the data A1, A2, . . . , A100. However, when the receiver receives pieces of data that are less than 100 pieces among the 110 pieces of data, the receiver decodes none of the data A1, A2, . . . , A100.

An AL-FEC encoding scheme having a systematic code characteristic is, for example, a raptorQ application layer forward error correction (RaptorQ AL-FEC) scheme. The RaptorQ AL-FEC scheme transmits a total of 110 pieces of data based on original data of A1, A2, . . . , A100, in such a way to use the original data of the 100 pieces of A1, A2, . . . , A100 as they are, generate B101, B102, . . . , B110, and transmit a total of 110 pieces of data of A1, A2, . . . , A100, B101, B102, . . . , B110 to a receiver. Herein, A1, A2, . . . , A100 are source symbols, and B101, B102, . . . , B110 are repair symbols. Although the receiver receives pieces of data that are less than 100 pieces among the 110 pieces of data so as to fail to recover all of the original data A1, A2, . . . , A100, the receiver may validly use the received ones of the original data A1, A2, . . . , A100 as they are. Also, when the receiver receives 100 pieces of data or more without distinguishing the source symbols from the repair symbols among the total of the 110 pieces of data, the receiver may recover all of the original data A1, A2, . . . , A100 although it fails to receive any one(s) of the original data A1, A2, . . . , A100. However, there is probability in which the receiver will fail to recover data although the receiver receives 100 pieces of data or more. When the receiver receives 100 pieces of data, the probability of recovery failure is 1/100, and when the receiver receives 101 pieces of data, the probability of recovery failure is significantly reduced to 1/10000.

The AL-FEC encoding scheme having the systematic code characteristic sets an amount of repair data considering a network average loss rate and an allowable recovery failure rate to secure target recovery reliability.

When an data packet has an error or is incomplete, the whole of the received data packet are discarded in an erasure channel. For example, when a cyclic redundancy check (CRC) error is found in a UDP packet received through a wireless network, the entire UDP packet is discarded.

Moreover, when the processing capacity of a router is not sufficient while a packet is transmitted together with packets that departed from another place on a network, the router discards the corresponding packet. UDP packets that are not retransmitted may be lost due to the reasons.

However, to apply AL-FEC, a state in which all source blocks are prepared needs to be preconditioned. Accordingly, to apply AL-FEC when a live broadcast is transmitted through broadcasting equipment, generation of a raptorQ repair symbol is delayed until an amount of data generated in real time reaches an amount of data corresponding to a source block.

### PRIOR ART DOCUMENTS

### Patent Documents

Korean Patent Application Publication No. 10-2017-0030235 (2017.03.17)
Korean Registered Patent Publication No. 10-2021872 (2019.09.18)

### Non-Patent Document

RFC 6330 “RaptorQ Forward Error Correction Scheme for Object Delivery”
RFC 5170 “Low Density Parity Check (LDPC) Staircase and Triangle Forward Error Correction (FEC) Schemes”

### SUMMARY

The disclosure provides an encoding apparatus and method for improving a raptorQ encoding delay time for a source block generated in real time.

It should be noted that objects of the present disclosure are not limited to the above-described objects, and other objects of the present disclosure will be apparent to those skilled in the art from the following descriptions.

Additional aspects will beset forth in part in the description which follows and, in part, will be apparent from the description, or may be learned by practice of the presented embodiments of the disclosure.

To overcome the above problem, an encoding apparatus according to the disclosure includes: a padding portion configured to add a padding symbol to a source block and generate an extended source block; an intermediate symbol generator configured to generate an intermediate symbol by using the extended source block; and an LT encoder configured to generate an encoded source block by using the intermediate symbol, wherein the intermediate symbol generator includes: a memory storing an original operation list according to Gaussian elimination; and an operation list rearranger configured to generate a rearranged operation list by rearranging an operation order of the original operation list according to a generation order of source symbols, and store the rearranged operation list in the memory.

According to an embodiment of the disclosure, the operation list rearranger may be further configured to generate the original operation list according to the number of input source symbols and store the original operation list in the memory.

According to an embodiment of the disclosure, the operation list rearranger may be further configured to generate the rearranged operation list under a condition that the source symbols are generated one by one.

According to an embodiment of the disclosure, the operation list rearranger may be further configured to store the rearranged operation list in the memory and then delete the original operation list from the memory.

According to an embodiment of the disclosure, the operation list rearranger may be further configured to store, in the memory, a rearrangement object list for managing operation information having been rearranged according to the generation order of source symbols or operation information incapable of being rearranged in the original operation list.

According to an embodiment of the disclosure, the rearranged operation list may include operation order information, first symbol information, second symbol information, operation content information, and a generation order of source symbols capable of being operated.

In this case, the operation list rearranger may be further configured to store, in the memory, an unavailable symbol list for managing information about a first symbol and a second symbol incapable of being used for operations according to the generation order of source symbols in the original operation list.

Also, the operation list rearranger may be further configured to rearrange, except for operations including the first symbol or the second symbol included in the unavailable symbol list in the original operation list, the remaining operations in the original operation list.

Also, the operation list rearranger may be further configured to rearrange all operations capable of being rearranged in the original operation list according to the generation order of source symbols, and then initialize the unavailable symbol list.

The intermediate symbol generator of the encoding apparatus according to the disclosure may further include an operator configured to perform operations according to the rearranged operation list by using source symbols generated up to an arbitrary operation start time.

To overcome the above problem, a method of rearranging an operation list, includes: operation (a) of generating, by a processor, a rearranged operation list by rearranging an operation order of an original operation list based on Gaussian elimination according to a generation order of source symbols; and operation (b) of storing, by the processor, the rearranged operation list in a memory.

The method according to the disclosure may further include, before the operation (a), generating, by the processor, the original operation list according to the number of input source symbols and storing the original operation list in the memory.

According to an embodiment of the disclosure, the operation (a) may include generating, by the processor, the rearranged operation list under a condition that the source symbols are generated one by one.

According to an embodiment of the disclosure, the operation (b) may further include storing the rearranged operation list in the memory and then deleting the original operation list from the memory.

According to an embodiment of the disclosure, the operation (a) may further include storing, by the processor, a rearrangement object list for managing operation information having been rearranged according to the generation order of source symbols or operation information incapable of being rearranged in the original operation list, in the memory.

According to an embodiment of the disclosure, the rearranged operation list may include operation order information, first symbol information, second symbol information, operation content information, and a generation order of source symbols capable of being operated.

In this case, the operation (a) may further include storing, by the processor, an unavailable symbol list for managing information about a first symbol and a second symbol incapable of being used for operations according to the generation order of source symbols in the original operation list, in the memory.

Also, the operation (a) may include rearranging, by the processor, except for operations including the first symbol or the second symbol included in the unavailable symbol list among the original operation list, the remaining operations in the original operation list.

Also, the operation (a) may further include rearranging, by the processor, all operations capable of being rearranged in the original operation list according to the generation order of source symbols, and then initializing the unavailable symbol list.

The method according to the disclosure may further include: padding operation (c) of adding, by the processor, a padding symbol to a source block and generating an extended source block; intermediate symbol generation operation (d) of generating, by the processor, an intermediate symbol by using the extended source block; and LT encoding operation (e) of generating, by the processor, an encoded source block by using the intermediate symbol, wherein the operation (d) may include performing, by the processor, operations according to the rearranged operation list by using source symbols generated up to an arbitrary operation start time. The method according to the disclosure may be implemented in a form of a computer program written to perform, on a computer, each operation of the method of rearranging the operation list, and recorded in a computer-readable recording medium.

Details of the disclosure are included in the detailed description and drawings.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic configuration diagram of a raptorQ encoder and a raptorQ decoder.

FIG. 2 is a reference view of a matrix A.

FIG. 3 is a block diagram of an intermediate symbol generator according to an embodiment of the disclosure.

FIG. 4 shows an example of an original operation list according to the disclosure.

FIG. 5 shows an example of a rearranged operation list according to an embodiment of the disclosure.

FIG. 6 shows reference examples of source symbols that need to be excluded upon rearrangement.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

An encoding method for application layer-forward error correction (AL-FEC) (hereinafter, simply referred to as an ‘encoding method’) according to the disclosure may be based on a raptorQ code written in “RFC 6330—RaptorQ Forward Error Correction Scheme for Object Delivery”. Accordingly, the disclosure may refer to and copy all content written in the RFC 6330.

To help understand the encoding method according to the disclosure, the raptorQ code will be briefly described. However, the following descriptions about the raptorQ code will be briefly given enough to help understand the encoding method according to the disclosure. Terms used in the disclosure are defined below.
Source block: data to be transmitted, an object to be encoded/decoded according to a raptorQ method, which may be divided into K source symbols.
Extended source block: K′ (K′≥K) source symbols, which are configured with a source block and a padding symbol.
Symbol: unit of data. Kinds of symbols include source symbols, padding symbols, repair symbols, intermediate symbols, etc., all of which have the same size.
Source symbol: a smallest unit of data that is used in an encoding process, which corresponds to information of a source block.
Padding symbol: symbol added to extend a source block to an extended source block. All data values are filled with ‘0’.
Repair symbol: symbol generated from a source block (or an extended source block). A symbol for repairing a source block considering loss predicted in a transmission process.
Intermediate symbol: symbol generated from a source symbol, a symbol generated in an intermediate process for generating a repair symbol, a symbol generated in an intermediate process for generating a lost source symbol in a raptorQ decoder.

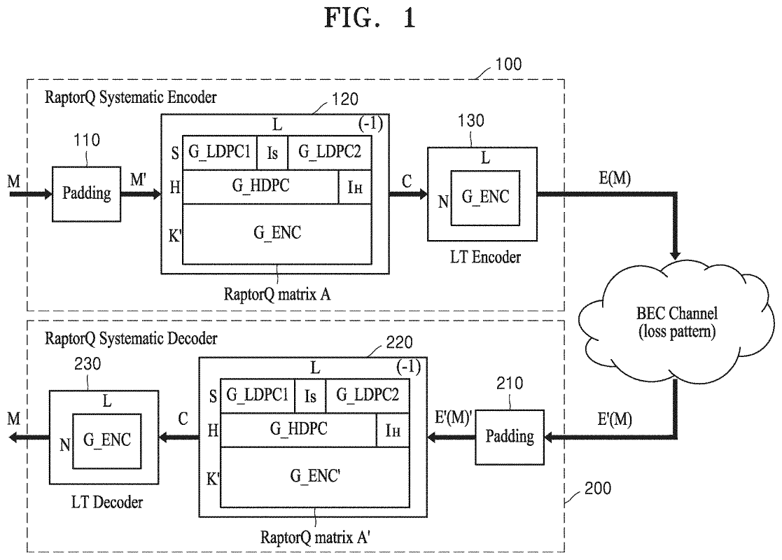

FIG. 1 is a schematic configuration diagram of a raptorQ encoder and a raptorQ decoder. An encoding process and a decoding process of a raptorQ code will be briefly described with reference to FIG. 1.

A transmitter may include a raptorQ systematic encoder (hereinafter, referred to as a ‘raptorQ encoder’) 100 for encoding a source block M by using a raptorQ code. More specifically, the raptorQ encoder 100 may include a padding portion 110, an intermediate symbol generator 120, and a luby transform (LT) encoder 130.

The padding portion 110 may add a padding symbol (padding data) to the source block M to generate an extended source block M′. Encoding according to a raptorQ code requires a predetermined number of source symbols (see 5.6 of RFC 6330). A situation in which a video is encoded at a constant bit rate (CBR) and transmitted through the Internet is assumed. In this situation, a source block having a predetermined size is generated at predetermined time periods, and, when the source block is transmitted through, for example, Ethernet, the source block needs to be divided into sizes of 1500 bytes (maximum transfer unit (MTU) of an Ethernet packet) or less and transmitted. It is assumed that the number of source symbols generated by dividing the source block M into predetermined sizes is K. Then, the K source symbols may not reach a number K′ (K′≥ K) determined in advance in the raptorQ code. In this case, padding symbols filled with ‘0’ may be added by the number of missing source symbols. For example, it is assumed that the source block M is divided into 100 source symbols having a predetermined size (K=100). According to 5.6 Table 2 of RFC 6330, a minimum number that is greater than or equal to 100 is ‘101’ (K′=101). Accordingly, a padding symbol may be added to generate an extended source block M′ having a total of 101 source symbols.

The intermediate symbol generator 120 may add S+H symbols filled with ‘0’ in front of the extended source block M′ to generate an L-dimensional column vector D, and apply (multiply) an inverse matrix of a matrix A for encoding of the raptorQ code to the L-dimensional column vector D to generate intermediate symbols C, wherein L is a natural number that is greater than or equal to 2 and L=K′+S+H.

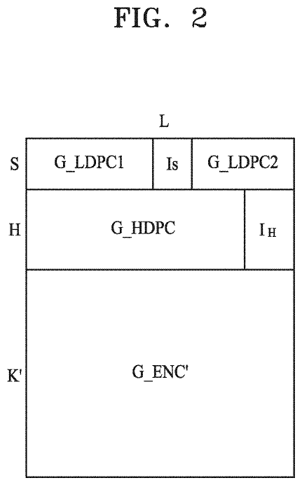

FIG. 2 is a reference view of the matrix A.

Referring to FIG. 2, the matrix A may be an L×L matrix. More specifically, the matrix A may include a low-density parity-check code (LDPC) matrix (G_LDPC1, G_LDPC2) having S rows, an S×S identity matrix (I_{S}), a high-density parity-check code (HDPC) matrix (G_HDPC) having H rows, an H×H identity matrix (I_{H}), and an encoding matrix (G_ENC′) having K′ rows (K≤K′), wherein S and H also are values determined in advance in 5.6 of RFC 6330. For example, S corresponding to the 101 source symbols K′ may be 17, and H corresponding to the 101 source symbols K′ may be 10. Accordingly, the matrix A may be a 128×128 matrix. According to an example, the intermediate symbol generator 120 may generate 128 intermediate symbols.

The LT encoder 130 may apply ENC[•], which is an encoding symbol generator, to the intermediate symbols C to generate a required number of repair symbols (RFC 6330 5.3.5.3), and combine the repair symbols and the source symbols to generate an encoded source block, that is, a message E(M). Dealing with the source symbols and the repair symbols in the same way may be a characteristic of raptorQ.

The message E(M) may be transmitted through an erasure channel (EC), and at this time, data loss may happen.

A receiver may include a raptorQ systematic decoder (hereinafter, referred to as a ‘raptorQ decoder’) 200 for decoding data (for example, a received message E′(M)) by using a raptorQ code. More specifically, the raptorQ decoder 200 may recover the source block M through decoding, and include a padding portion 210, an intermediate symbol generator 220, and an LT decoder 230.

The padding portion 210 may add a padding symbol to the received message E′(M) to generate a message E′(M)′. The intermediate symbol generator 220 may apply (multiply) an inverse matrix of a matrix A′ (a raptorQ code matrix) for decoding the raptorQ code to the message E′(M)′ to generate the intermediate symbols C, wherein the matrix A′ is an L×L matrix. However, component values of the matrix A′ may depend on numbers of source symbols and repair symbols actually received by the raptorQ decoder 200. When a part of the source symbols is missing so that a part of the column vector D is replaced by repair symbols, the matrix A′ may become different from the matrix A used by the raptorQ encoder 100. More specifically, the matrix A′ may include an LDPC matrix (G_LDPC1, G_LDPC2) having S rows, an S×S identity matrix (Is), an HDPC matrix (G_HDPC) having H rows, an H×H identity matrix (IF), and an encoding matrix (G_ENC′) having at least K′ rows.

The LT decoder 230 may apply ENC[•], which is an encoding symbol generator, to the intermediate symbols C to generate the missing source symbols (RFC 6330 5.3.5.3), thereby repairing an original source block.

General operations of the raptorQ encoder 100 and the raptorQ decoder 200 are well-known, and therefore, detailed descriptions thereof will be omitted.

Returning again to the encoding process, the raptorQ encoder 100 may need to generate the intermediate symbols C to encode the source block M. A relationship between the matrix A and the intermediate symbols C is as follows.

AC=D

Herein, D is the column vector resulting from adding the S+H symbols filled with ‘0’ in front of the extended source block, that is, the L-dimensional column vector configured with the source symbols. To obtain the intermediate symbols C, an inverse matrix of the matrix A may be needed.

C=A⁻¹D

However, a task of actually calculating the inverse matrix of the matrix A is not easy. According to the above-described example (K′=101), the matrix A may be a 128×128 matrix. Furthermore, because the raptorQ code allows a maximum number K′ of 56,403 for extended source blocks, the matrix A may be a 57,326×57,326 matrix in the largest case. Therefore, it is not easy to calculate an inverse matrix of such a matrix A. Fortunately, as a method of obtaining an inverse matrix of the matrix A, there is Gaussian elimination. The Gaussian elimination is a well-known mathematic algorithm, and therefore, descriptions about the principle of the Gaussian elimination will be omitted in the disclosure.

Referring to 5.4.2 of RFC 6330, as a method of generating the intermediate symbols C, a calculation method including 5 phases is proposed. The 5 phases are a process of applying the inverse matrix of the matrix A to the column vector D to calculate a result value, and are configured with phased operations using a formal characteristic of the matrix A, although based on the principle of the Gaussian elimination. A first phase of the 5 phases may occupy 50% or more of an operation count of all the 5 phases, and consume 85% or more of the amount of computations of a processor. An operation list of the disclosure may include only operations of the first phase.

Moreover, the above-described encoding process may include a prerequisite condition. There is a precondition that the source block, that is, data to be transmitted, is input in complete states to the raptorQ encoder 100. Accordingly, in the case of live broadcast video data, a source block is generated in real time, and a task of generating a repair symbol does not start until the source block is completely generated because the source block is not input to the raptorQ encoder 100. A delay caused by a time taken to generate live broadcast video data may act as an intrinsic delay time that is not overcome by high computing ability of hardware. Accordingly, in an environment where a source block is generated in real time, a more efficient encoding method may be needed.

To overcome the above-described encoding delay, the present applicant has proposed a method of performing an operation for generating an intermediate symbol in advance by using a source symbol generated up to a present time in real time without waiting until all source blocks are generated, as disclosed in Korean Registered Patent Application No. 10-2021872. However, when the method is performed, operations capable of being performed in advance in an operation list may be in real time distinguished from operations incapable of being performed in advance in the operation list, which increases the number of times that a memory is referred to. Accordingly, the disclosure proposes a method capable of reducing the number of times that the memory is referred to during an operation process to a level that is similar to that of a typical raptorQ operation, while overcoming the encoding delay.

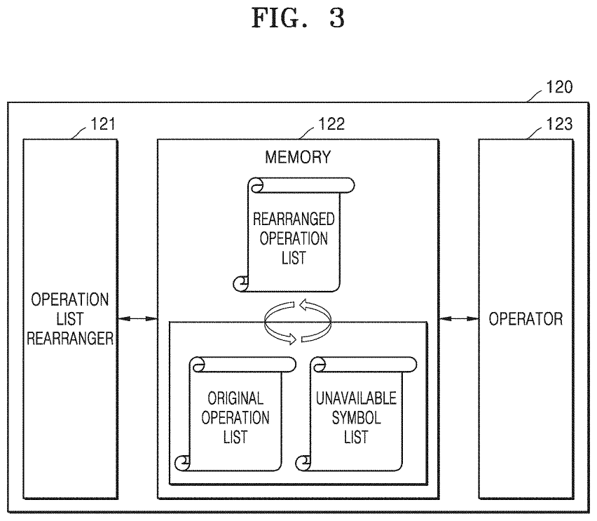

FIG. 3 is a block diagram of an intermediate symbol generator according to an embodiment of the disclosure.

Referring to FIG. 3, the intermediate symbol generator 120 according to the disclosure may include a memory 122 and an operation list rearranger 121.

The memory 122 may store an original operation list according to Gaussian elimination.

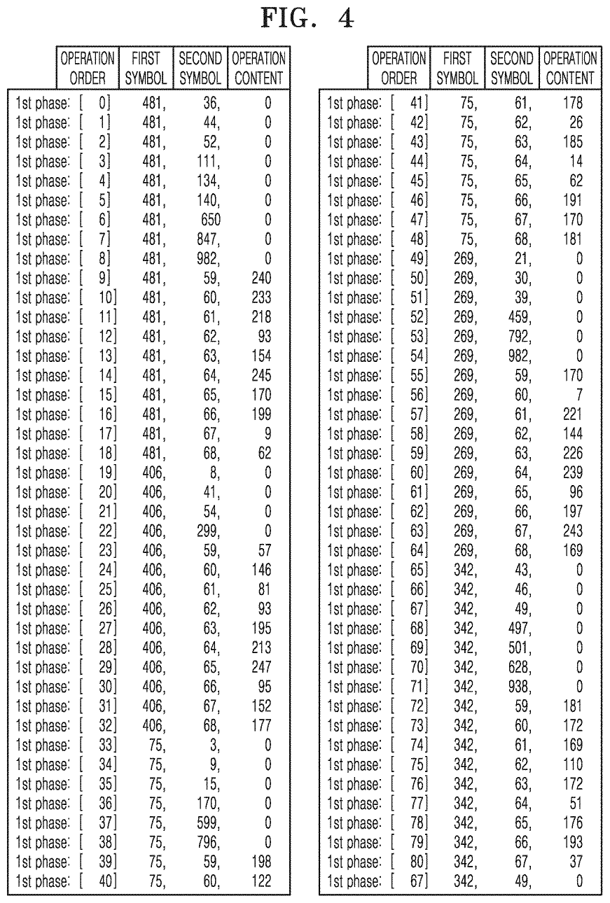

FIG. 4 shows an example of an original operation list according to the disclosure.

Referring to FIG. 4, the original operation list according to the disclosure may include operation order information, first symbol information, second symbol information, and operation content information. The original operation list may include first phase information of operation information for calculating intermediate symbols from source symbols according to Gaussian elimination. That is, when all operations between the source symbols are completed according to an operation order written in the original operation list and operations of the sequential second to fifth phases, the intermediate symbols may be calculated from the source symbols.

The raptorQ encoder 100 and the raptorQ decoder 200 may have agreed on values of S, H, and K′ in advance, and a detailed form of the matrix A that is used by the raptorQ encoder 100 may be determined according to the values of S, H, and K′. The original operation list may be determined and fixed by a principle suggested in RFC 6330 5.4.2 from the detailed form of the matrix A.

The operation order information may represent information about an order in which operations will be performed. The first symbol information and the second symbol information may represent information about symbols on which operations will be performed. The operation content information may represent content of operations that are performed between the first symbol and the second symbol. More specifically, it is an operation (RFC 6330 5.7) on a Galois field having 256 components (GF256), which means in detail that a bitwise exclusive OR (XOR) operation may be performed on a first symbol and a second symbol when a number of operation content information is 0, and, when the number of the operation content information is not 0, the first symbol may be multiplied by the number of the operation content information on the GF 256 and then a bitwise XOR operation (RFC 6330 5.7.2) may be performed on the result of the multiplication and the second symbol.

For example, a first operation in the original operation list shown in FIG. 4 may be content of “perform a bitwise XOR operation on a value of a first symbol of a number 481 and a value of a second symbol of a number 36 and store a result value in the second symbol of the number 36”. Both the first symbol and the second symbol may be any symbols which are the components of the vector D. In the above example, the first symbol of the number 481 may be a symbol of a number 481 of the vector D and the second symbol of the number 36 may be a symbol of a number 36 of the vector D.

Also, an operation of a number 9 in the original operation list shown in FIG. 4 may be content of “perform an octet production on each octet value of the first symbol of the number 481 and 240 which is a number in the GF 256 on the GF 256, perform a bitwise XOR operation on the result value and a second symbol of a number 59, and store the result value in the second symbol of the number 59”.

According to an embodiment of the disclosure, the original operation list may have been stored in advance in the memory 122. Herein, ‘in advance’ means before the encoding apparatus according to the disclosure is first booted from an off state to an on state. The encoding apparatus according to the disclosure and the raptorQ decoder 200 may have set values of S, H, and K′ in advance. That is, what L×L matrix to use may have been set in advance according to the number of input source symbols. Operation content according to Gaussian elimination based on a size of a matrix set in advance may have been determined in advance, and an original operation list including the operation content according to Gaussian elimination may have been stored in advance in the memory 122.

According to another embodiment of the disclosure, the original operation list may be generated as necessary and then stored in the memory 122. The encoding apparatus according to the disclosure and the raptorQ decoder 200 may have set no values of S, H, and K′. That is, the number of input source symbols may change as necessary. For example, it may be assumed that the encoding apparatus according to the disclosure may change the number of symbols of an extended source block depending on an external input, such as an input from a user, an input from the raptorQ decoder 200, etc. In this case, storing all operation lists according to Gaussian elimination corresponding to all selectable numbers of symbols of an extended source block in the memory 122 may require an excessive storage space, which is inefficient. Accordingly, generating an original operation list when the number of source symbols is determined by an external input, etc. and storing the original operation list in the memory 122 may be more efficient. In this case, the operation list rearranger 121 may generate an original operation list according to the number of input source symbols and store the original operation list in the memory 122. A time at which the operation list rearranger 121 generates the original operation list may be, for example, a time at which the encoding apparatus according to the disclosure is first booted from an off state to an on state.

The operation list rearranger 121 may generate an operation list (hereinafter, referred to as a ‘rearranged operation list’) by rearranging an operation order of the original operation list according to a generation order of the source symbols, and store the rearranged operation list in the memory 122. To store the rearranged operation list in the memory 122, a storage space required for a task of generating the rearranged operation list may be assigned in the memory 122.

As described above, to overcome the raptorQ encoding delay, a method of in advance performing an operation for generating intermediate symbols by in real time searching operations capable of being performed with source symbols generated in real time from the original operation list has been used in Korean Registered Patent Application No. 10-2021872. However, the method needs to in real time repeat a process of searching operations capable of being performed with source symbols generated in real time from the original operation list, and also repeatedly perform the process on the following source block. In regard to the problem, the present applicant has found that an operation for generating intermediate symbols may be more efficiently performed by rearranging operable content in order from the original operation list according to a generation order of source symbols. The rearranged operation list according to the disclosure may be data obtained by arranging an operation order of operation content included in the original operation list according to a generation order of the source symbols.

According to an embodiment of the disclosure, the operation list rearranger 121 may generate the rearranged operation list under an assumption (condition) that the source symbols are generated one by one. This will be described in more detail, as follows. It is assumed that two source symbols are initially generated. Also, the operation list rearranger 121 may search for an operation capable of being performed with the first and second source symbols in the original operation list from top to bottom. When the operation list rearranger 121 searches for the operation capable of being performed with the first and second source symbols, the operation list rearranger 121 may transfer content of the corresponding operation to an uppermost portion of a new list (a storage space assigned in the memory 122). When the operation list rearranger 121 finishes or fails to search for the operation capable of being performed with the first and second source symbols, it is assumed that a next source symbol is additionally generated. Then, the operation list rearranger 121 may search again for an operation capable of being performed with the fisrt three source symbols in the original operation list. At this time, the operation list rearranger 121 may determine whether an operation is capable of being performed with the first source symbol, the second source symbol, and the third source symbol. In other words, the operation list rearranger 121 may determine whether an operation is capable of being performed according to a generation order of source symbols. When an available operation exists, the operation list rearranger 121 may transfer content of the corresponding operation to the new list (a storage space assigned in the memory 122) starting from the uppermost portion, sequentially. When no available operation exists, it may be assumed that a next source symbol is generated. In this way, the operation list rearranger 121 may perform a task of transferring operable content in the original operation list in order, that is, a rearrangement task under an assumption that source symbols, such as a fourth source symbol, a fifth source symbol, etc., are sequentially generated. However, there may be a case in which, although both a first symbol and a second symbol of an operation on the original operation list have already been generated, a determination that the operation is unavailable needs to be made considering a relationship with another operation. To make the determination, an unavailable symbol list may be managed, which will be described later.

To make the determination, the operation list rearranger 121 may store a rearrangement object list for managing operation information having been rearranged according to a generation order of source symbols or operation information incapable of being rearranged, in the original operation list, in the memory 122. That is, the rearrangement object list may be management information for efficiently managing a task of sequentially rearranging operation content.

Whether each operation in the original operation list has been rearranged may be managed in a form of a flag such that an operation already rearranged under a condition of previously generated source symbols is not again rearranged. The operation list rearranger 121 may repeatedly perform the process many times until a final source symbol constituting a source block is generated, that is, until all operations in the original operation list are rearranged.

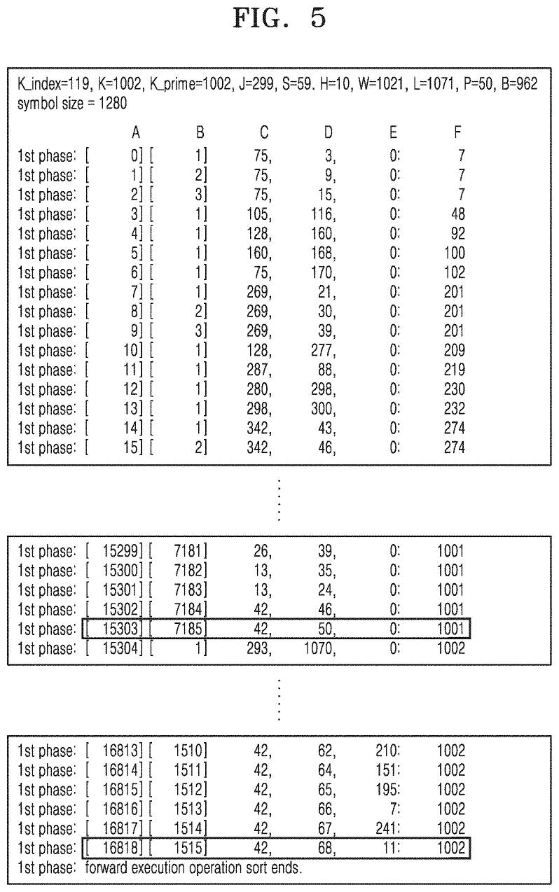

FIG. 5 shows an example of a rearranged operation list according to an embodiment of the disclosure.

Referring to FIG. 5, an ‘A’ column may be information about an operation order in the rearranged operation list. ‘C, D, and E’ columns may be information about a first symbol, a second symbol, and operation content, like FIG. 4. An ‘F’ column may be information about a generation order of source symbols that are capable of being operated. For example, when source symbols are generated until a source symbol of a number 7, this means that 0, 1, and 2 of the A column are operable. A ‘B’ column may be information about operation orders among the operations with the same F column value. For example, the ‘B’ column may include information representing that when the source symbols are generated until the source symbol of the number 7, operations are performed in an order of 0, 1, and 2 of the ‘A’ column.

When a table corresponding numbers of the ‘F’ column to numbers of the ‘A’ column is separately created, a final number of operations capable of being performed in the rearranged operation list according to a final number of generated source symbols may be easily searched. When a plurality of rows of the ‘A’ column correspond to the same number of the ‘F’ column, the operation list rearranger 121 may correspond a number of the lowermost one among the rows of the ‘A’ column to the number of the ‘F’ column.

Moreover, after the rearranged operation list is completely generated, the original operation list may not be needed. In other words, this is a case in which the intermediate symbol generator 120 uses the rearranged operation list to generate intermediate symbols, without using the original operation list. In this case, the operation list rearranger 121 may store the rearranged operation list in the memory 122, and then delete the original operation list from the memory 122.

Moreover, referring again to FIG. 3, the intermediate symbol generator 120 according to the disclosure may further include an operator 123 for performing an operation according to the rearranged operation list by using source symbols generated until an arbitrary operation start time. The raptorQ encoder 100 according to the disclosure, more specifically, the intermediate symbol generator 120 may perform operations capable of being performed in advance with source symbols input up to a present time, without waiting until all source symbols constituting a source block are input. ‘source symbols generated until an operation start time’ in the disclosure may mean source symbols stored in the memory 122.

For example, it is assumed that a source symbol of a number 209 among a total of 1,002 symbols (K=1,002, K′=1,002, S+H=69) has been generated until an arbitrary operation start time. Although considering that S+H symbols filled with ‘0’ exist at the head of the vector D and K′−K padding symbols exist at the end of the vector D, generated symbols may correspond to symbols from a symbol of a number 1 to a symbol of a number 278 of the vector D, the number of the F column in FIG. 5 means the number of the generated source symbols, that is, 209 in this case. Referring to the rearranged operation list shown in FIG. 5, operations may be performed until a number 10 of the A column corresponding to a row containing a number 209 of the F column. Accordingly, the operator 123 may perform operations until the operation of the number 10 of the rearranged operation list, and then wait without performing an operation of a number 11 until a symbol of a number 219 is generated.

Unlike the typical raptorQ encoding waiting until all source symbols constituting a source block are generated, performing operations in advance by using source symbols generated in real time may prevent a time delay compared to the typical raptorQ encoding, which has been described through the Korean Registered Patent Publication No. 10-2021872. Briefly, for example, in case of K=1002, 16,819 operations may be needed. When a source symbol immediately before a final source symbol, that is, a 1001^{st} source symbol, is generated, operations up to an operation of a number 15,303 may be performed. Accordingly, 15,304 operations among the total of 16,819 operations may have been performed when the source symbol immediately before the final source symbol is generated, and the 15,304 operations may correspond to 90.99% of a total of operations. Accordingly, a time delay of 90% may be prevented compared to the typical raptorQ encoding (the first phase of the 5 phases according to 5.4.2 of RFC 6330) of performing operations after all source symbols are generated.

Furthermore, when the operator 123 according to the disclosure uses the rearranged operation list, it may be possible to relatively reduce the number of memory accesses. For a relative comparison, a case of using the method disclosed in the Korean Registered Patent Publication No. 10-2021872, that is, a case of using an original operation list, is assumed. In this case, the operator 123 may perform a process of searching operations, which is capable of being performed with source symbols generated until an arbitrary operation start time, from the original operation list and performing the operations while reading the original operation list from first to last, once, and repeat a task of checking source symbols additionally generated during the process and reading again the original operation list from first to last until all source symbols are generated. In this case, assuming that 5 source symbols on average are additionally generated while the operator 123 reads the original operation list once, the operator 123 may need to read the original operation list about 200 (1002/5=200) times on average for each source block, and, while the operator 123 reads the original operation list once, the operator 123 may need to access and read the first symbol and the second symbol among the original operation list of 16819 lines. Therefore, a total of 6.7 (200×16819×2) million memory accesses may be needed. Although operations once completed among the operations in the original operation list are managed not to be again referred to in the next operation, a total of 3.35 million memory accesses on average, which are half of the 6.7 million memory accesses, may be needed. When an average number of source symbols additionally generated while the operator 123 reads the original operation list once is reduced, the number of memory accesses may increase inverse proportionally. That is, when a high performance processor is used to search operations capable of being performed in the original operation list within a shorter time, computing ability may be more significantly wasted.

Moreover, once the rearranged operation list according to the disclosure is generated, a source symbol, when being generated, may be just operated according to an operation order of the rearranged operation list, and accordingly, only 34 thousand (16819×2) memory accesses may be needed to read the first and second symbols of the rearranged operation list.

A reduction in the number of memory accesses may also relate to a reduction in an operation time. Times taken to generate intermediate symbols according to three methods when a symbol size is 1280 bytes and the number of source symbols is 1002 are compared. A first method is the typical raptorQ encoding method, a second method is the method of generating intermediate symbols with symbols generated in real time without rearranging an operation list, as disclosed in the Korean Registered Patent Publication No. 10-2021872, and a third method is the method of generating intermediate symbols with symbols generated in real time by using an rearranged operation list. As an experimental condition, a process of generating intermediate symbols from a completely generated source block was performed 1000 times, and average times thereof were calculated. As a result, the first method resulted in 23,869 us, the second method resulted in 45,974 us, and the third method resulted in 23,994 us. The encoding method according to the disclosure corresponds to the third method. Comparing the third method to the second method, the third method showed speed improved by about 48% compared to the second method. The operation time is a time taken to perform all the first to fifth phases for generating intermediate symbols, and as described above, the first phase of the 5 phases occupies 50% or more of an operation count of all the operations of the first to fifth phases, and consumes 85% or more of the amount of computations of a processor. In this regard, the third method showed speed improved by about 56% compared to the operations of the first phase. Comparing the third method to the first method, the third method showed speed that is similar to that of the first method. The result was obvious because the same operations were performed in different orders. However, the first method, that is, the typical raptorQ encoding method starts an operation after all source symbols are generated, whereas the third method, that is, the raptorQ encoding method according to the disclosure, starts an operation while source symbols are generated in real time so that a major portion of operations of an operation list is completed before a final source symbol is generated. Therefore, the first method and the third method showed similar time taken to generate each intermediate symbol starting from a first operation of the operation list, as seen from the above-mentioned values. However, the third method showed a significantly shorter delay time taken to generate an intermediate symbol from when a first source symbol is generated, than the first method. More specifically, as described above, 90% of the operations of the first phase may be performed in advance before the final source symbol is generated, the operations of the first phase may occupy 50% or more of an operation count of all the operations of the first to fifth phases, and the operations of the first phase may consume 85% or more of the amount of computations of a processor. In this regard, 83% of the operation time of the first to fifth phases required to generate intermediate symbols may be performed in advance. In sum, the case of using the rearranged operation list according to the disclosure may reduce a delay time by about 83% with the same level of operations as the case of using the original operation list.

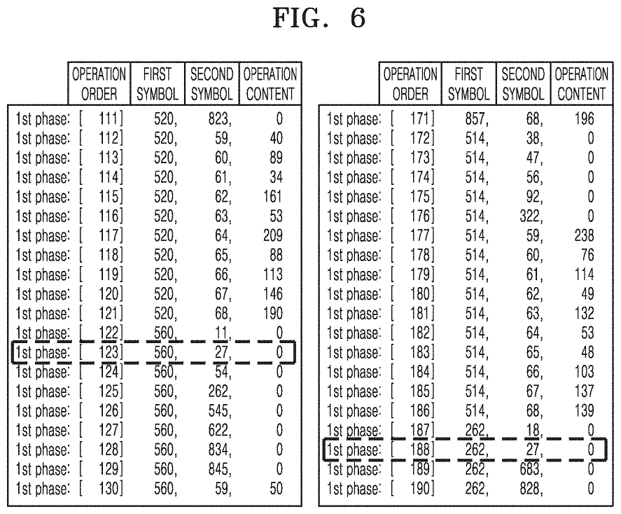

The operation list rearranger 121 may store an unavailable symbol list for managing information about a first symbol and a second symbol incapable of being used for operations according to a generation order of source symbols in the original operation list, in the memory 122. The unavailable symbol list may be information for identifying operation content incapable of being transferred to rearranged operation list according to a generation order of source symbols when a task of rearranging operation content included in the original operation list is performed. Accordingly, the operation list rearranger 121 may rearrange, except for operations including the first symbol or the second symbol included in the unavailable symbol list in the original operation list, the remaining operations. The unavailable symbol list will be described with reference to FIG. 6, below.

FIG. 6 shows reference examples of source symbols that need to be excluded upon rearrangement.

Referring to FIG. 6, it is assumed that up to the symbol of the number 500 of the vector D has been generated. An operation order of a number 123 may include content representing that “operate a first symbol of a number 560 and a second symbol of a number 27”. The operation order of the number 123 may be incapable of being rearranged because the first symbol of the number 560 has not yet been generated. Thereafter, an operation order of a number 188 may include content representing that “operate a first symbol of a number 262 and the second symbol of the number 27”. In this case, the operation order of the number 188 may be considered to be capable of being rearranged because the first symbol of the number 262 and the second symbol of the number 27 have already been generated. However, the operation order of the number 188 may have not to be rearranged. The original operation list may be operation content based on Gaussian elimination. When the operation order of the number 188 in the original operation list is first operated according to a rearranged order, a result value is stored in the symbol of the number 27, then the symbol of the number 560 is generated, and the operation order of the number 123 in the original operation list is operated according to the rearranged order, the operation of the number 123 may be performed by using a value that is different from a value of the symbol of the number 27 that needs to be originally used for the operation of the number 123. As a result, a result value which is different from a final result value for applying the inverse matrix of the matrix A will be calculated. Accordingly, the first symbol or the second symbol related to operations incapable of being rearranged according to a generation order of source symbols may need to be excluded hereafter from all objects that are to be rearranged. However, it may be also possible to exclude only the second symbol due to a characteristic of the operations of the first phase that the number in the first symbol column does not again appear in the second symbol column on the original operation list after appearing once in the first symbol column on the original operation list.

After rearranging all operations capable of being rearranged in the original operation list according to a generation order of source symbols, the operation list rearranger 121 may initialize the unavailable symbol list. The unavailable symbol list may be for the decision whether the operations in the original operation list are incapable of being rearranged with source symbols generated up to a present time. When a next source symbol is generated, whether or not the corresponding first symbol or the corresponding second symbol is operable may need to be newly determined and managed. Accordingly, initializing the unavailable symbol list may be a task of erasing information about symbols included in the unavailable symbol list and searching for components of the vector D corresponding to source symbols not generated up to a present time. More specifically, because the S+H symbols at the head of the vector D are symbols filled with ‘0’, the symbols are always recognized, and because the K′−K symbols at the end of the vector D also are padding symbols filled with ‘0’, the symbols are also recognized. Therefore, the unavailable symbol list may be initialized with numbers corresponding to source symbols not yet generated among source symbols in a middle portion of the vector D.

Moreover, although the raptorQ encoder 100 described above is shown to have configurations separated according to results of individual performances in the drawings, the raptorQ encoder 100 may be implemented as a processor known in the technical field to which the disclosure belongs to, an application-specific integrated circuit (ASIC), another chipset, a logic circuit, a register, a communication modem, a data processor, etc.

Also, the encoding method according to the disclosure may be implemented in the form of a computer program written to perform operations of the above-described encoding apparatus and recorded in a computer-readable recording medium.

The computer program may include computer language code, such as C, C++, C#, JAVA, Python, machine language, or the like, that can be read by the processor (for example, a CPU) of the computer through the device interface of the computer, for the computer to read the program to execute the methods implemented as the program. Such code may include functional code related to a function or the like that defines necessary functions for executing the above methods, and include control code related to an execution procedure necessary for the processor of the computer to execute the functions in a predetermined procedure. Further, such code may further include memory reference related code about whether the additional information or media needed to cause the processor of the computer to execute the functions should be referred to at any location (address) of the internal or external memory of the computer. Also, when the processor of the computer needs to communicate with any other computer or server that is remote to execute the functions, the code may further include communication related code such as how to communicate with any other computer or server in the remote by using a communication module of the computer, and what information or media should be transmitted and received during communication.

The medium to be stored is not a medium for storing data for a short time such as a register, a cache, a memory, etc., but means a medium that semi-permanently stores data and is capable of being read by a device. Specifically, examples of the medium to be stored include ROM, RAM, CD-ROM, magnetic tape, floppy disk, optical data storage, and the like, but are not limited thereto. That is, the program may be stored in various recording media on various servers to which the computer can access, or on various recording media on a user's computer. In addition, the medium may be distributed to a network-connected computer system so that computer-readable codes may be stored in a distributed manner.

According to the disclosure, when a source block is generated in real time, it may be possible to improve an encoding delay time compared to the typical raptorQ encoding method.

It should be noted that effects of the disclosure are not limited to those described above and other effects of the disclosure will be apparent to those skilled in the art from the following descriptions.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An encoding apparatus comprising:
a padding portion configured to add a padding symbol to a source block and generate an extended source block;
an intermediate symbol generator configured to generate an intermediate symbol by using the extended source block; and
an LT encoder configured to generate an encoded source block by using the intermediate symbol,
wherein the intermediate symbol generator comprises:
a memory storing an original operation list according to Gaussian elimination; and
an operation list rearranger configured to generate a rearranged operation list by rearranging an operation order of the original operation list according to a generation order of source symbols and store the rearranged operation list in the memory.

2. The encoding apparatus of claim 1, wherein the operation list rearranger is further configured to generate the original operation list according to the number of input source symbols and store the original operation list in the memory.

3. The encoding apparatus of claim 1, wherein the operation list rearranger is further configured to generate the rearranged operation list under a condition that the source symbols are generated one by one.

4. The encoding apparatus of claim 1, wherein the operation list rearranger is further configured to store the rearranged operation list in the memory and then delete the original operation list from the memory.

5. The encoding apparatus of claim 1, wherein the operation list rearranger is further configured to store, in the memory, a rearrangement object list for managing operation information having been rearranged according to the generation order of source symbols or operation information incapable of being rearranged in the original operation list.

6. The encoding apparatus of claim 1, wherein the rearranged operation list includes operation order information, first symbol information, second symbol information, operation content information, and a generation order of source symbols capable of being operated.

7. The encoding apparatus of claim 6, wherein the operation list rearranger is further configured to store, in the memory, an unavailable symbol list for managing information about a first symbol and a second symbol incapable of being used for operations according to the generation order of source symbols in the original operation list.

8. The encoding apparatus of claim 7, wherein the operation list rearranger is further configured to rearrange, except for operations including the first symbol or the second symbol included in the unavailable symbol list in the original operation list, the remaining operations in the original operation list.

9. The encoding apparatus of claim 7, wherein the operation list rearranger is further configured to rearrange all operations capable of being rearranged in the original operation list according to the generation order of source symbols, and then initialize the unavailable symbol list.

10. The encoding apparatus of claim 1, wherein the intermediate symbol generator further comprises an operator configured to perform operations according to the rearranged operation list by using source symbols generated up to an arbitrary operation start time.

11. A method of rearranging an operation list, the method comprising:
operation (a) of generating, by a processor, a rearranged operation list by rearranging an operation order of an original operation list based on Gaussian elimination according to a generation order of source symbols; and
operation (b) of storing, by the processor, the rearranged operation list in a memory.

12. The method of claim 11, further comprising, before the operation (a), generating, by the processor, the original operation list according to the number of input source symbols and storing the original operation list in the memory.

13. The method of claim 11, wherein the operation (a) comprises generating, by the processor, the rearranged operation list under a condition that the source symbols are generated one by one.

14. The method of claim 11, wherein the operation (b) further comprises storing the rearranged operation list in the memory and then deleting the original operation list from the memory.

15. The method of claim 11, wherein the operation (a) further comprises storing, by the processor, a rearrangement object list for managing operation information having been rearranged according to the generation order of source symbols or operation information incapable of being rearranged in the original operation list, in the memory.

16. The method of claim 11, wherein the rearranged operation list includes operation order information, first symbol information, second symbol information, operation content information, and a generation order of source symbols capable of being operated.

17. The method of claim 16, wherein the operation (a) further comprises storing, by the processor, an unavailable symbol list for managing information about a first symbol and a second symbol incapable of being used for operations according to the generation order of source symbols in the original operation list, in the memory.

18. The method of claim 17, wherein the operation (a) comprises rearranging, by the processor, except for operations including the first symbol or the second symbol included in the unavailable symbol list in the original operation list, the remaining operations in the original operation list.

19. The method of claim 17, wherein the operation (a) further comprises rearranging, by the processor, all operations capable of being rearranged in the original operation list according to the generation order of source symbols, and then initializing the unavailable symbol list.

20. The method of claim 11, further comprising:
padding operation (c) of adding, by the processor, a padding symbol to a source block and generating an extended source block;
intermediate symbol generation operation (d) of generating, by the processor, an intermediate symbol by using the extended source block; and
LT encoding operation (e) of generating, by the processor, an encoded source block by using the intermediate symbol,
wherein the operation (d) comprises
performing, by the processor, operations according to the rearranged operation list by using source symbols generated up to an arbitrary operation start time.

21. A non-transitory computer-readable recording medium storing instructions, when executed, configured to perform a method of rearranging an operation list, the method comprising:
generating, by a processor, a rearranged operation list by rearranging an operation order of an original operation list based on Gaussian elimination according to a generation order of source symbols; and
storing, by the processor, the rearranged operation list in a memory.
